(19) United States
(12) Patent Application Publication
(10) Pub. No.: US 2005/0174746 A1
(43) Pub. Date: Aug. 11, 2005

(54) LGA contact with pair of cantilever arms

(75) Inventors: Shihwei Hsiao, Tu-Chen (TW); Chao-Chung Cheng, Tu-Chen (TW); Yao-Chi Huang, Tu-Chen (TW)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 11/053,094

(22) Filed: Feb. 7, 2005

(30) Foreign Application Priority Data
Feb. 6, 2004 (TW) 93201656

(51) Int. Cl. H05K 1/00

(52) U.S. Cl. 361/769

(57) ABSTRACT

An LGA contact (50) comprises a retention body (51) and a pair of arms (52, 55) extending respectively from opposite sides of the retention body for electrically mating with corresponding conductive members (40, 60), respectively. Each arm is formed with a resiliently deformable hand (53, 56). In use, the two hands of the pair of arms are each resiliently pressed against each other to establish an extra electrical path on the contact. With this configuration of the contact, even though the hands each are devised to be relatively long or short, secure and steady electrical engagement between the hands can be assured and the impedance of the contact is securely and efficiently decreased.

### CROSS-REFERENCE TO RELATED APPLICATIONS

This application is related to application Ser. No. 10/635,626, filed on Aug. 5, 2003 and allowed, and application Ser. No. 10/658,430, filed on Sep. 8, 2003 and now pending.

### BACKGROUND OF THE INVENTION

1. Field of the Invention

The present invention is directed to the art of electrical connectors having contacts arranged thereon in a high-density manner, and especially to a land grid array (LGA) contact configured with a pair of cantilever arms upon which are mechanically elastically pressed to electrically bridge an electrical substrate such as a printed circuit board (PCB) and a integrated circuit (IC) interface such as an LGA package.

2. Description of the Prior Art

With the development of electronic components toward the miniaturization and high-density trends, the electronic components are devised to be increasingly small and arranged in a more and more compact manner. Especially in the electronic connector field, contacts or terminals are configured to be increasingly small, and planted on corresponding housings in a high-density manner.

During the development of the electronic connector field, one big problem is encountered. As well known in the electronic connector field, the closer arrangement of adjacent contacts on housings, and the higher inductance among the adjacent contacts. To decrease inductance between the contacts, it is an efficient and preferred way to bring impedance of each contact down.

Previously, the contact 90 shown in FIG. 8 is widely used to electrically bridge a PCB and an IC package, such as an LGA package, with a pair of arms 91, 92 respectively electrically mating with corresponding conductive members, e.g. pads, arranged on the PCB and IC package beforehand. Apparently, only one main electrical path on the contact 90 is applied to communicate between the PCB and the IC package. With this configuration of the contact 90, the impedance of the contact 90 may be prone to be too high to catch up with the trends.

A developed manner is invented to improve the contact 90 of FIG. 8. As shown in FIG. 9, the improved terminal 80 is equipped with a U-shaped arm 82. In use, the arm 82 is compressed to have a distal end 84 thereof electrically engaged with a retention portion 83 of the terminal 80. As a result, two electrical paths are established between a PCB and an IC package. This devise of the terminal 80 brings the impedance of the terminal down.

However, the terminal 80 has a U-shaped and cantilever-like configuration. This relatively complex configuration may bring much trouble in accurately designing or/and manufacturing a length of the terminal 80. Further, if the distal end 84 is formed to be longer than normal or standard, the distal end 84 abuts against on the retention portion 83 while a pad of the IC package is pressed on a topmost engaging portion 85 of the terminal 80. Additionally, the distal end 84 and a part of the retention portion 83 on which the distal end 84 abuts have relatively inferior resilient characteristics. As a result, the IC package is prone to be supported by the engaging portions 85, instead of a housing (not shown) receiving the terminals 80. Abutting of the distal end 84 against on the part of the retention portion 83 is relatively unreliable, speak differently, engagement between the terminals 80 and the IC package is unreliable. Additionally, if the distal end 84 is formed to be shorter than normal or standard, the distal end 84 may be prone to unreliably electrically engage with the retention portion 83, even can not touch the retention portion 83.

Accordingly, a new and secure contact, which can overcome all the above-mentioned disadvantages, is desired.

### SUMMARY OF THE INVENTION

Accordingly, one main object of the invention is to provide an electrical contact with ability to securely and efficiently assure low impedance thereof.

To fulfill the above object, an electrical contact is provided according to the present invention. The electrical contact has a retention body and a pair of arms extending respectively from opposite sides of the retention body for electrically mating with corresponding conductive members, respectively. Each arm is formed with a hand. In use, the two hands of the pair of arms are pressed against each other to resiliently deform to make mating parts of the two hands move toward each other and abut against each other to establish an extra electrical path on the contact.

With this configuration of the contact compared with the prior contacts, the hands can be devised to be relatively long enough so that the hands both can resiliently deform to assuredly make the mating parts thereof engage with each other in use. Secure and steady electrical engagement between the hands can still be assured, and the impedance of the contact is securely and efficiently decreased.

### BRIEF DESCRIPTION OF THE DRAWINGS

The features of the present invention which are believed to novel are set forth with particularity in the appended claims. The invention, together with its objects and the advantages thereof, may be best understood by reference to the following detailed description taken in conjunction with the accompanying drawings, in which like reference numerals identify like elements and in which:

FIG. 1 is an isometric view of an electrical connector having a dielectric housing and electrical contacts provided according to a preferred embodiment of the present invention, together with an IC package and a PCB ready to mate with the electrical connector;

FIG. 2 is a partial cross-section view of the housing, showing contact-passageways in which corresponding contact are to be inserted;

FIG. 3 is an isometric view of one contact of FIG. 1;

FIG. 4 is a partial cross section view of the contacts being received in corresponding contact-passageways;

FIG. 5 is similar to FIG. 4, but showing a cross section view vertical to the cross section view of the FIG. 4 and the contacts ready to mate with the PCB and the IC package;

FIG. 6 is similar to FIG. 5, but showing an intermediate transition state of mating the PCB and the IC package with the contacts;

FIG. 7 is similar to FIG. 6, but showing that the PCB and the IC package fully engage with the contacts;

FIG. 8 is an enlarged, isometric view of a convenient contact; and

FIG. 9 is an enlarged, isometric view of another convenient contact.

### DESCRIPTION OF PREFERRED EMBODIMENTS OF THE INVENTION

Reference will now be made to the drawings to describe the present invention in detail.

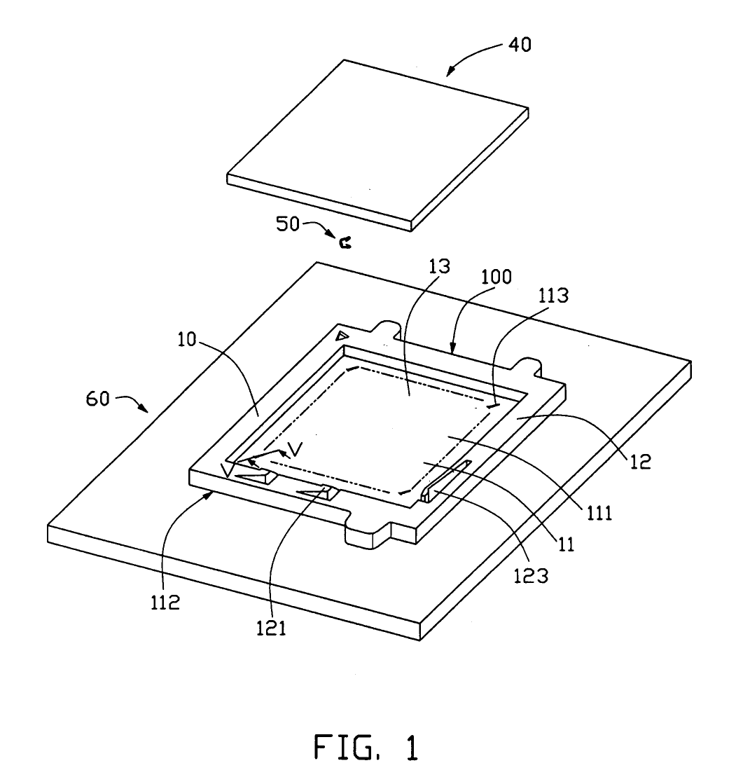

Referring to FIG. 1, an electrical connector 100 is shown on which contacts 50 according to a preferred embodiment of the present invention are planted. The electrical connector 100 is mainly used to electrically bridge two electrical interfaces. In the preferred embodiment, the two electrical interfaces are an IC package 40 and a PCB 60.

The electrical connector 100 comprises a dielectric housing 10 of substantially rectangular configuration and a plurality of contacts 50 planted on the housing 10.

The housing 10 has a substantially rectangular bottom floor 11 and four side walls 12 end to end raised from edges of the bottom floor 11. The floor 11 and the side walls 12 cooperatively define a cavity 13 for engagingly receiving the IC package 40 therein. One side wall 12 is formed with a pair of spaced first cantilever arms 121 each having an engaging part thereof extended into the cavity 13. Another side wall 12 adjacent said one side wall 13 is formed with a second cantilever arm 123 with a pressing part in the cavity 13. The engaging parts and the pressing part are used to cooperatively position the IC package 40 in the cavity 13 in a horizontal plane parallel to the bottom floor 11.

The floor 11 has top and bottom surfaces 111, 112, and defines a substantially rectangular array of contact-passageways 113 between the top and bottom surfaces 111, 112.

Referring also to FIG. 2, each contact-passageway 113 has a major section 114 extending through the housing, with a pair of slots 115 defined in opposite sides of the contact-passageway 113 and adjacent another side of the contact-passageway. Each slot 115 is formed with a bottom surface 116 for supporting a corresponding contact 50 (detailed hereinafter).

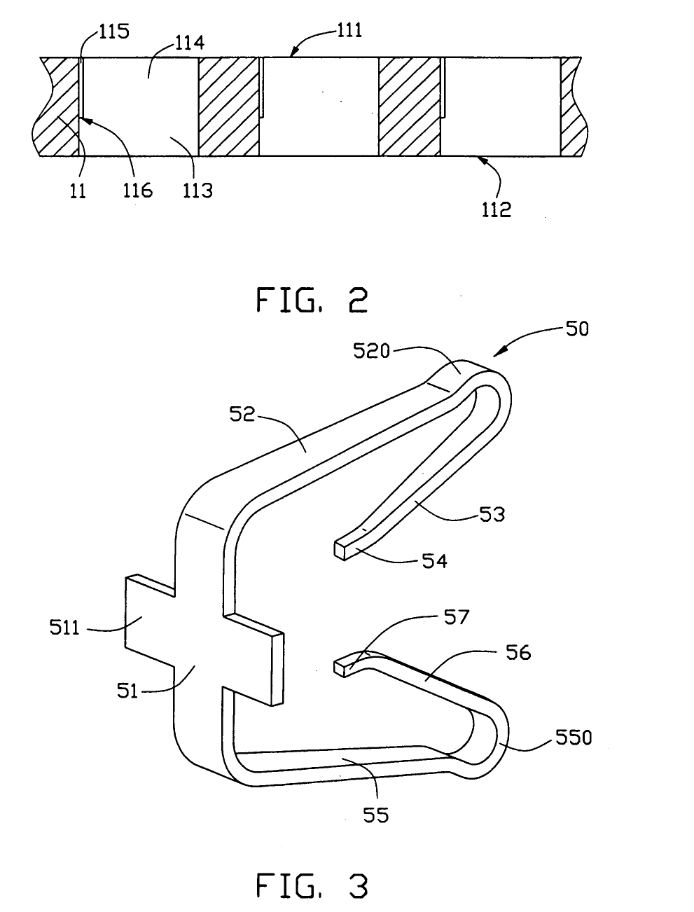

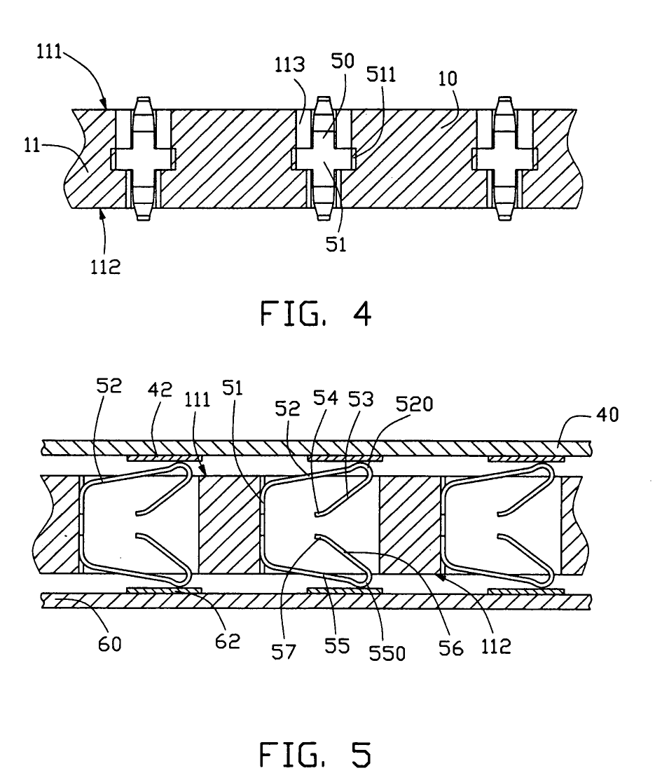

Referring to FIG. 3, each contact 50 comprises a vertical plate-like retention body 51 with a pair of ears 511 outwardly and coplanarly extending from middles of opposite lateral sides of the body 51.

An upper resilient arm 52 upwardly and outwardly extends from a top side of the retention body 51, and is formed with an upper engaging section 520 at a distal end thereof. An upper resilient leg 53 downwardly and inwards extends from the upper engaging section 520, and is formed with an upper mating section 54 near a distal end thereof.

A lower resilient arm 55 has a configuration similar to the upper arm 52. The lower arm 55 downwardly and outwardly extends from a bottom side of the retention body 51, and is formed with a lower engaging section 550 at a distal end thereof. A lower resilient leg 56 upwardly and inwards extends from the lower engaging section 550, and is formed with a lower mating section 57 near a distal end thereof.

The upper arm 52, the upper engaging section 520, the upper leg 53 and the upper mating section 54 are respectively corresponded to the lower arm 55, the lower engaging section 550, the lower leg 56 and the lower mating section 57 in a vertical direction.

With the configuration of the contact 50, the upper leg 53 and the lower leg 57 can be devised to be long enough to assure engagement between the upper mating section 54 and the lower mating section 57 in use.

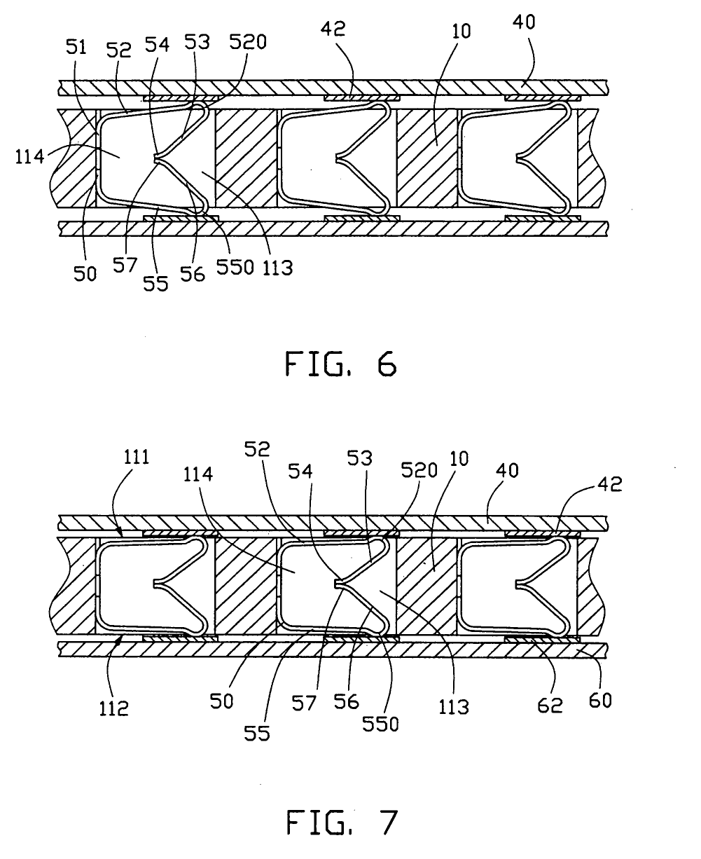

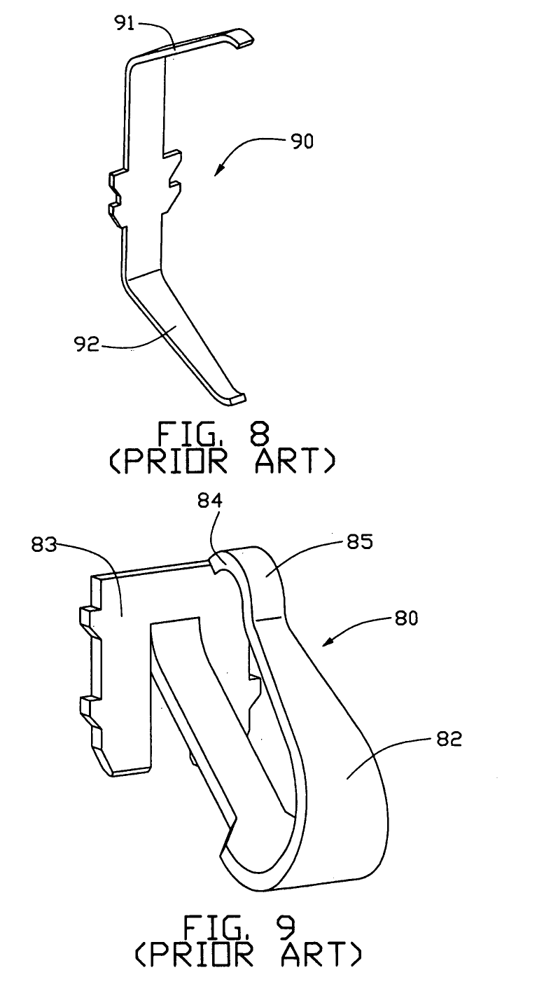

Referring to FIGS. 1, 2, 3 and 6, in assembly, each contact 50 is loaded from a top of the housing 10, and securely planted in a corresponding contact-passageway 113, with the lower arm 55 and a part of the lower leg 56 loading through the major section of the contact-passageway 113 and the pair of ears 511 engagingly respectively interfering with inner sides of the slots 115 of the corresponding contact-passageway 113.

Referring also to FIG. 7, in order to prevent the contact 50 from over-sliding down, each slot 115 upright extends and is terminated substantially at a half of a height of the floor 11 from a top of the floor 11. Additionally, the slot 115 is formed with a shoulder surface 116 for supporting the pair of ears 511 of the contact 50 in a height direction of the housing 10.

In use, the connector 100 is sandwiched between the PCB 60 and the IC package 40 which are parallel to each other, with each upper engaging section 520 corresponding to a top pad 42 arranged on the IC package 40 and each lower engaging section 550 corresponding to a bottom pad 62 arranged on the PCB 60.

The PCB 60 or/and the IC package 40 is urged to close toward each other, thereby making the top and bottom pads 42, 62 press against the upper and lower engaging sections 520, 550, respectively.

Further pressing, the upper and lower arms 52, 55 are bent to generate elastic force to assure steadily mechanical and electrical engagement between the top and bottom pads 42, 62 and the upper and lower engaging sections 520, 550.

When the upper and lower arms 52, 55 are bent to the degree that the upper mating section 54 and a corresponding lower mating section 57 touch each other, an extra electrical path on the contact 50 is established. As a result, impedance of the contact 50 is decreased.

When the contact 50 is further compressed by the IC package 40 or/and the PCB 60, the upper and lower legs 53, 56 both elastically deform in a plane parallel to the height direction of the housing 10. The IC package 40 and the PCB 60 are fastened to the housing 10, instead of the contacts 50. This further strengthens steady engagement between the upper and lower engaging sections 520, 550 and the top and bottom pads 42, 62.

Until the electrical connector 100 is fully engaged with the IC package 40 and the PCB 60, the upper and lower engaging sections 520, 550 fully mate with the top and bottom pads 42, 62 and the upper and lower mating sections 54, 57 engage with each other. Two electrical paths are completely bridged between the IC package 40 and the PCB 60 by the electrical connector 100.

Since the upper leg 53 and the lower leg 57 of each contact 50 can be devised to be long enough and thus have good resilient characteristics to assure engagment between the upper mating section 54 and the lower mating section 57 in use, the IC package 40 can be securely mounted on the housing 10, instead of being unreliably supported by all of the upper engaging sections 520. Reliable electrical engagement between the IC package 40 and the contacts 50 is assured.

Furthermore, although the present invention has been described with reference to a preferred embodiment, it is not to be construed as being limited thereto. Various alterations and modifications can be made to the embodiments without in any way departing from the scope or spirit of the present invention as defined in the appended claims.

1. An electrical contact comprising:
an electrical path and first and second half electrical paths being electrically connected with two opposite ends of said electrical path, respectively;
wherein whether the contact is in use or not, the electrical path is established on the contact all the time, while the first and second half electrical paths is electrically connected together to establish a second electrical path between said opposite ends only when the contact is in use; and
wherein the first and second half electrical paths each have a mating part and a resiliently deformable arm being connected with the mating part, when the contact is in use, the two mating parts of the first and second half electrical paths are urged to close toward each other in a direction until the two arms deform in a plane parallel to said direction to generate elastic force to make the two mating parts fully mechanically and electrically engage with each other to achieve said second electrical path.

2. The electrical contact as claimed in claim 1, wherein between the electrical path and the first path is a joint part for electrically engaging with a corresponding exterior conductive member, and between the electrical path and the second path is another joint section for electrically mating with another corresponding exterior conductive member, said joint part and said joint sections are respectively located at topmost and bottommost positions of the contact in said direction.

3. The electrical contact as claimed in claim 1, wherein said electrical path comprises a body with a major surface, upper and lower resilient cantilever-like parts extending from opposite ends of said body, respectively, said joint part and said joint sections are respectively formed on distal ends of said upper and lower resilient cantilever-like parts.

4. The electrical contact as claimed in claim 3, wherein said joint part and said joint sections are located respectively further from the body than the mating parts in a direction vertical to the major surface of the body.

5. The electrical contact as claimed in claim 3, wherein the body is formed with a pair of retention ears at opposite lateral sides thereof.

6. The electrical contact as claimed in claim 5, wherein said mating parts are arranged symmetrically relative to the pair of retention ears.

7. The electrical contact as claimed in claim 5, wherein said joint part and said joint sections are arranged symmetrically relative to the pair of retention ears.

8. An electrical connector comprising:
a dielectric housing defining top and bottom surfaces and an array of passageways between said top and bottom surfaces; and
a plurality of conductive members respectively received in corresponding passageways, each of the conductive members having a retention part secured in a corresponding passageway, an upper arm extending upwardly from the retention part with an engaging portion left above the top surface for electrically engaging with an exterior conductive member, a lower arm extending downwardly from the retention part with a mating portion left beyond the bottom surface for electrically mating with another exterior conductive member; an upper leg being connected to the upper arm and extending downwardly with an engaging part; and a lower leg being connected to the lower arm with a mating part;
wherein when the engaging portion and/or the mating portion are compressed, the upper arm and the lower arm deform to make the engaging part and the mating part close toward each other until the upper leg and the lower leg resiliently deform to generate elastic force to assure mechanical and electrical engagement between the mating part and the engaging part.

9. The electrical connector as claimed in claim 8, wherein each of the passageways comprising a large section through which the lower arm is loaded, and a pair of slot-like sections in communication with said large section, the retention part has a pair of ears engagingly received in said pair of slot-like sections, respectively.

10. The electrical connector as claimed in claim 9, wherein each of said pair of slot-like sections extends from said top surface and is terminated in the housing with a shoulder surface for supporting the contact received in the corresponding passageway.

11. The electrical connector as claimed in claim 8, wherein the upper arm and the lower arm are arranged symmetrically with respect to the retention part.

12. The electrical connector as claimed in claim 11, wherein the upper leg and the lower leg are arranged symmetrically with respect to the retention part.

13. The electrical connector as claimed in claim 8, wherein when the engaging part and the mating part are urged to close along a direction to electrically engage with each other, the upper and lower legs resiliently deform in a plane parallel to said direction.

14. The electrical connector as claimed in claim 8, wherein the retention part defines a major surface, the engaging portion and the mating portion are respectively located further from the retention part than the engaging part and the mating part in a direction vertical to the major surface of the mating part.

15. An electrical connector assembly comprising:
an insulative housing defining a plurality of passageways extending therethrough in a vertical direction; and
a plurality of conductive terminals dispose din the corresponding passageways, respectively, each of said terminals including a retention part retaining the terminal within the corresponding passageway, an upper section extending upward from an upper end of the retention part and above the an upper face of the housing, a lower section extending downwardly from a lower end of the retention part and below a lower face of the housing; wherein
said upper section defines a relatively lower region, said lower section defines a relatively higher region, said lower region being spaced from said higher region in said vertical direction when said terminal is in a relaxed manner, but engaged with each other in said vertical direction when said terminal is in a compressed manner under a condition that the upper section and said lower section are compressed toward each other by corresponding electronic components disposed around said upper face and said lower face, respectively.

16. The electrical connector assembly as claimed in claim 15, wherein the lower region and the higher region are essentially parallel to each other for normally confronting each other in said vertical direction.
